(19) United States
(12) Patent Application Publication
(10) Pub. No.: US 2010/0142160 A1
(43) Pub. Date: Jun. 10, 2010

(54) ELECTRONIC DEVICE

(75) Inventors: Lucas Huang, Shenzhen City (CN); Lee-Han Ng, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignee: FIH (Hong Kong) Limited, Kowloon (HK)

(21) Appl. No.: 12/392,926

(22) Filed: Feb. 25, 2009

(30) Foreign Application Priority Data
Dec. 5, 2008 (CN) 200810305998.0

(51) Int. Cl. H05K 5/00

(52) U.S. Cl. 361/748; 361/679.01

(57) ABSTRACT

An electronic device is described that includes a body member and a cable. The cable is mounted to and received in the body member.

### BACKGROUND

### Technical Field

The present disclosure relates to an electronic device and, particularly, to an electronic device incorporating a retractable cable.

### BRIEF DESCRIPTION OF THE DRAWINGS

Many aspects of the electronic device can be better understood with reference to the following drawings. These drawings are not necessarily drawn to scale, the emphasis instead being placed upon clearly illustrating the principles of the present electronic device. Moreover, in the drawings like reference numerals designate corresponding sections throughout the several views.

FIG. 1 is an isometric view of an electronic device, in accordance with an exemplary embodiment.

FIG. 2 is a first state of the electronic device, shown in FIG. 1.

FIG. 3 is a second state of the electronic device, shown in FIG. 1.

### DETAILED DESCRIPTION OF EXEMPLARY EMBODIMENT

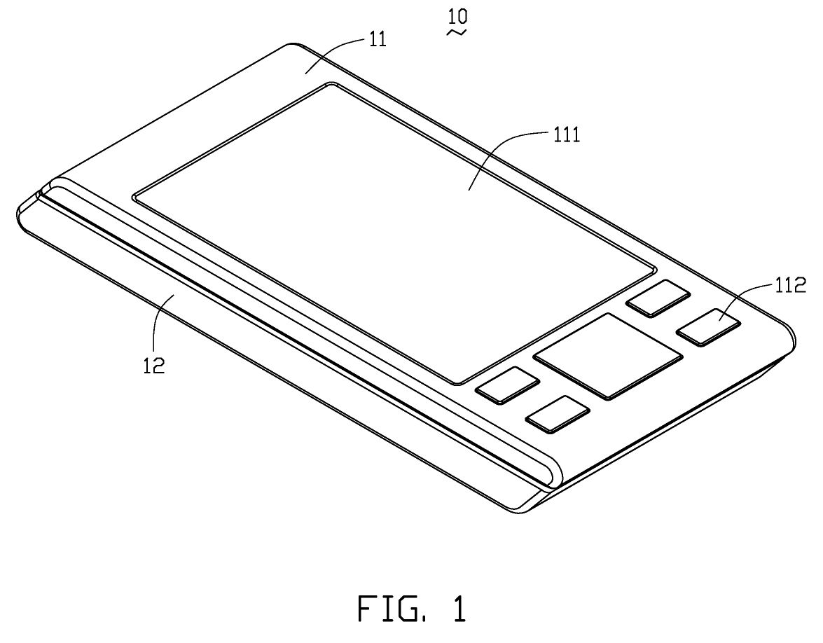

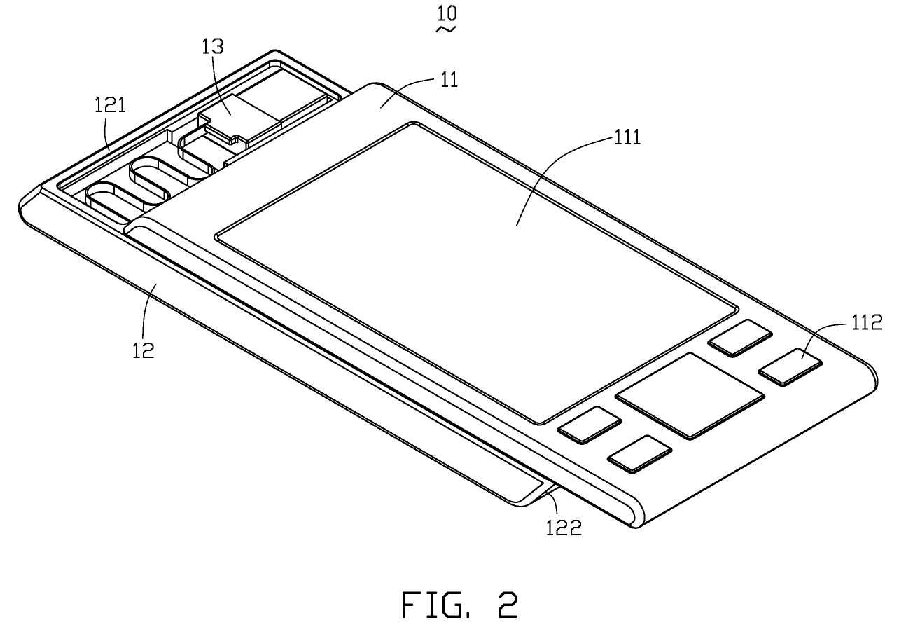

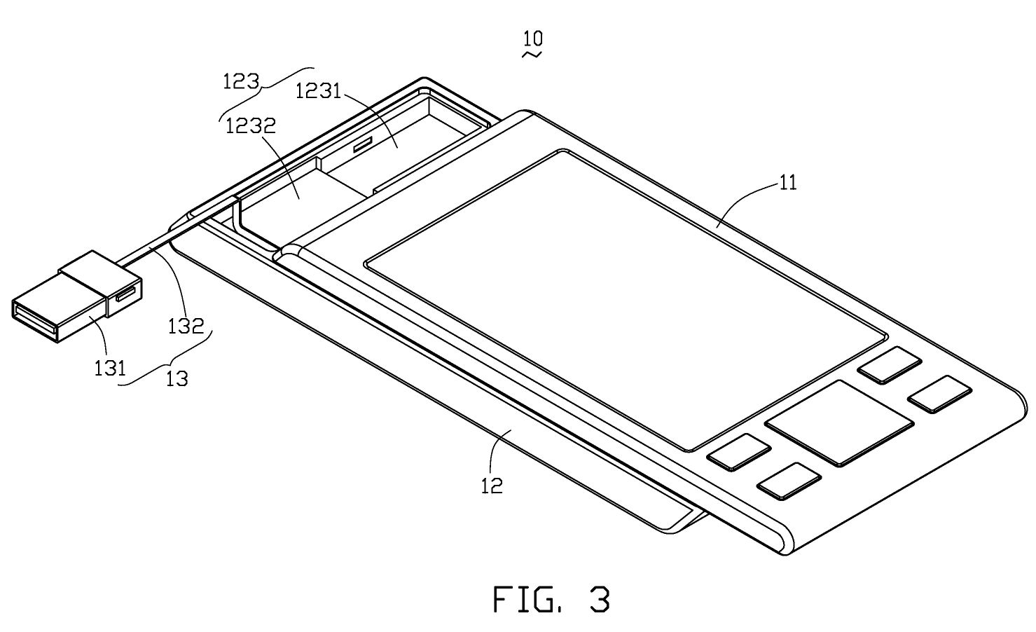

FIGS. 1 through 3 show an exemplary electronic device 10 including a cover member 11, a body member 12 and a cable 13. The cover member 11 is slidably mounted to the body member 12. The cable 13 is configured to allow communication between the electronic device 10 and some other electronic device. The cable 13 is connected to the body member 12 and shielded by the cover member 11.

The cover member 11 is a generally thin sheet-shaped piece. The cover member 11 defines a display 111 and a plurality of buttons 112 adjacent to the display 111.

The body member 12 is also a generally thin sheet-shaped piece. The body member 12 includes a top end 121 and an opposite bottom end 122. The body member 12 defines a receiving slot 123 adjacent to the top end 121. The receiving slot 123 includes a first slot section 1231 and a second slot section 1232 communicating with the first slot section 1231. The cover member 11 is slidably mounted to the body member 12 to expose or close off the receiving slot 123.

The cable 13 includes a head member 131 and a connecting cable 132. One end of the connecting cable 132 is connected to a PCB within the body member 12 and the other end of the connecting cable 132 is connected to the head member 131. The head member 131 may be a universal serial bus (USB) configured connector. The head member 131 is received in the first slot section 1231. The connecting cable 132 is received in the second slot section 1232.

In use, the cover member 11 is slid towards the bottom end 122 of the body member 12 until the receiving cavity 123 is exposed. At this stage, a user can easily takes out the cable 13 to connect the electronic device 10 to another electronic device (not shown).

The electronic device 10 has the cable 13 integrated therewith, avoiding the trouble of carrying a separate cable and possibly losing it. Having it integrated with the phone will also prevent the users from having to find and purchase cables that are compatible with the electronic device.

It is to be understood, however, that even through numerous characteristics and advantages of the present invention have been set forth in the foregoing description, together with details of the structure and function of the invention, the disclosure is illustrative only, and changes may be made in detail, especially in matters of shape, size, and arrangement of sections within the principles of the invention to the full extent indicated by the broad general meaning of the terms, in which the appended claims are expressed.

What is claimed is:

1. An electronic device, comprising:
a body member; and
a cable received in the body member.

2. The electronic device as claimed in claim 1, wherein the body member defines a receiving slot, the receiving slot sized to receive the cable.

3. The electronic device as claimed in claim 2, further including a cover member, the cover member is slidably mounted to the body member and slidable between an open and a closed position.

4. The electronic device as claimed in claim 3, wherein the cable includes a head member and a connecting cable, one end of the connecting cable is connected to a printed circuit board within the body member, and the other end of the connecting cable is connected to the head member.

5. The electronic device as claimed in claim 4, wherein the receiving slot includes a first slot section and a second slot section communicating with the first slot section, the first slot section receives the head member, and the second slot section receives the connecting cable.

6. The electronic device as claimed in claim 4, wherein the head member is an universal serial bus.

7. The electronic device as claimed in claim 3, wherein the cover member defines a display and a plurality of buttons adjacent to the display.

8. An electronic device, comprising:
a body member;
a cable received in the body member; and
a cover member slidably mounted to the body member between an open and a closed position.

9. The electronic device as claimed in claim 8, wherein the body member defines a receiving slot, the receiving slot being sized to receive the cable.

10. The electronic device as claimed in claim 9, wherein the cable includes a head member and a connecting cable, one end of the connecting cable is connected to a printed circuit board within the body member, and the other end of the connecting cable is connected to the head member.

11. The electronic device as claimed in claim 10, wherein the receiving slot includes a first slot section and a second slot section communicating with the first slot section, the first slot section receives the head member, and the second slot section receives the connecting cable.

12. The electronic device as claimed in claim 10, wherein the head member is an universal serial bus.

13. The electronic device as claimed in claim 3, wherein the cover member defines a display and a plurality of buttons adjacent to the display.

14. An electronic device, comprising:
a body member;
a cable received in the body member; and
a cover member slidably mounted to the body member and used for closing off or exposing the cable.
